(19) United States
(12) Patent Application Publication
(10) Pub. No.: US 2012/0090884 A1
(43) Pub. Date: Apr. 19, 2012

(54) PRINTED CIRCUIT BOARD

(75) Inventors: TSUNG-SHENG HUANG, Tu-Cheng (TW); YING-TSO LAI, Tu-Cheng (TW); CHUN-JEN CHEN, Tu-Cheng (TW); WEI-CHIEH CHOU, Tu-Cheng (TW)

(73) Assignee: HON HAI PRECISION INDUSTRY CO., LTD., Tu-Cheng (TW)

(21) Appl. No.: 12/981,460

(22) Filed: Dec. 29, 2010

(30) Foreign Application Priority Data
Oct. 18, 2010 (TW) 99135464

(51) Int. Cl. H05K 1/11

(52) U.S. Cl. 174/266

(57) ABSTRACT

A printed circuit board includes a plurality of power layers. Each power layer defining a number of vias arranged in a number of rows. The number of the power layers is N (N>3). The power layers are defined as a 1st, 2nd, . . . , Nth power layer. The vias of the 1st power layer are connected to other power layers by a step-shaped connection means.

### TECHNICAL FIELD

The disclosure generally relates to printed circuit boards, particularly to a printed circuit board with even current distribution.

### DESCRIPTION OF RELATED ART

Referring to FIGS. 4 and 5, a multi-layer printed circuit board 200 includes four power layers 201. A plurality of vias 202 are defined in each power layer 201. The vias 202 are arranged in a 3×4 matrix. The three rows are labeled R1-R3. The four lines are labeled 1-4. Wherein, the vias 202 arranged in row R1 are adjacent to a power supply of the printed circuit board 200, the vias 202 arranged in row R3 are adjacent to loads such as transistors of the printed circuit board 200. The power supply supplies electrical power to the loads through the vias 202 arranged in the rows R1, R2 and R3.

The vias 202 of the 1st power layer 201 are connected to the vias 202 of the 2nd, 3rd, and 4th power layers 201 in the same row. That is, the vias 202 of each power layer 201 are all connected

However, when the power supply provides electrical power to the loads, the current mostly flows through the vias 202 arranged in or adjacent to the row R1 of the 1st power layer 201. Referring to FIG. 6, current flowing through the vias 202 arranged in the row R1 are much higher than through the vias 202 arranged in the other rows. Thus, current distribution of the printed circuit board 200 is uneven, and the printed circuit board 200 may be damaged by overheating in the areas with more current and have a shorter lifespan.

Therefore, there is room for improvement within the art.

### BRIEF DESCRIPTION OF THE DRAWINGS

Many aspects of the printed circuit board can be better understood with reference to the following drawings. The components in the drawings are not necessarily drawn to scale, the emphasis instead being placed upon clearly illustrating the principles of the printed circuit board.

FIG. 1 is schematic view of a printed circuit board, according to an exemplary embodiment.

FIG. 2 is a cross section view taken along line II-II of FIG. 1.

FIG. 3 is a table of current flowing through vias of a 1st power layer of the printed circuit board of FIG. 1.

FIG. 4 is schematic view of a conventional printed circuit board.

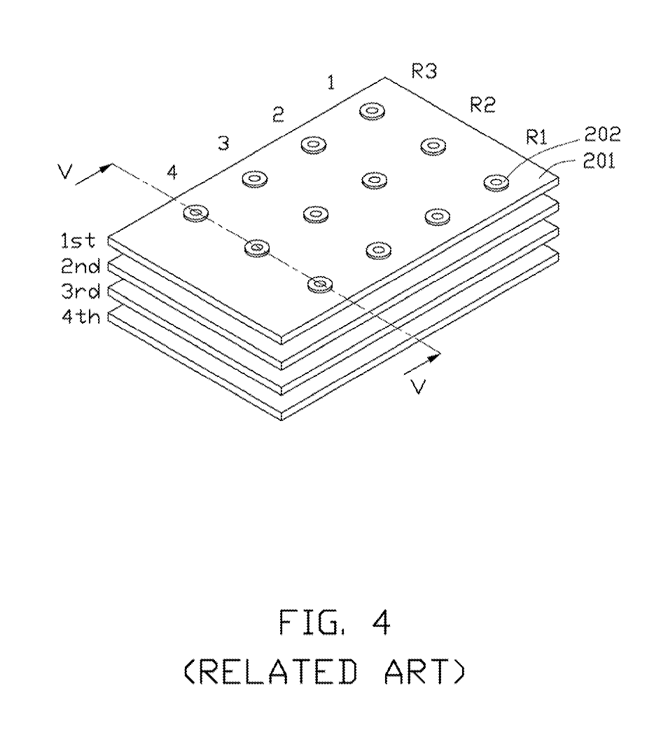

FIG. 5 is a cross section view taken along line V-V of FIG. 4.

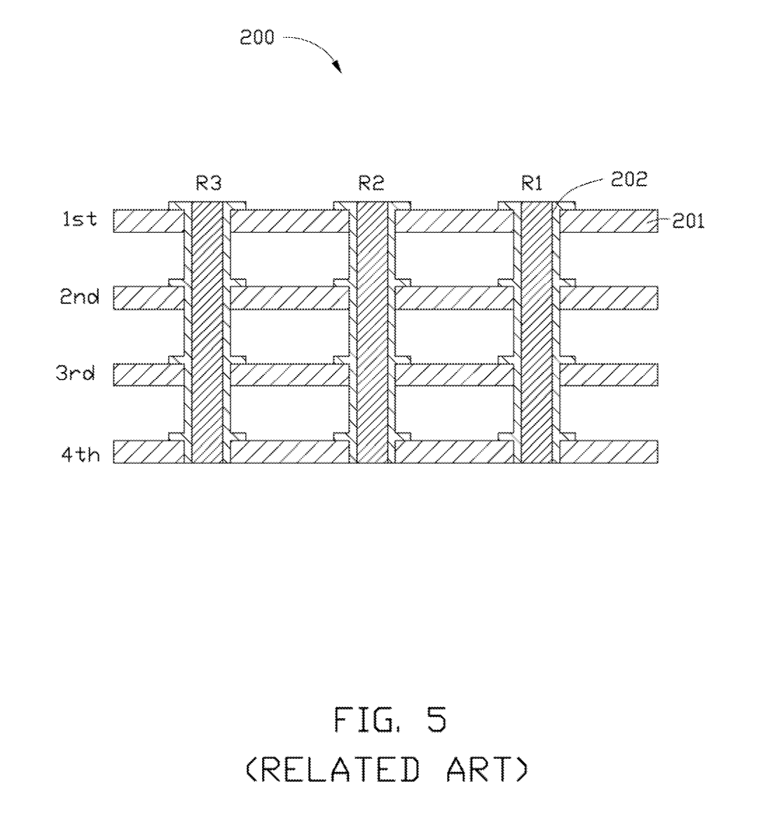

FIG. 6 is table of current flowing through vias of a first power layer of the printed circuit board of FIG. 4.

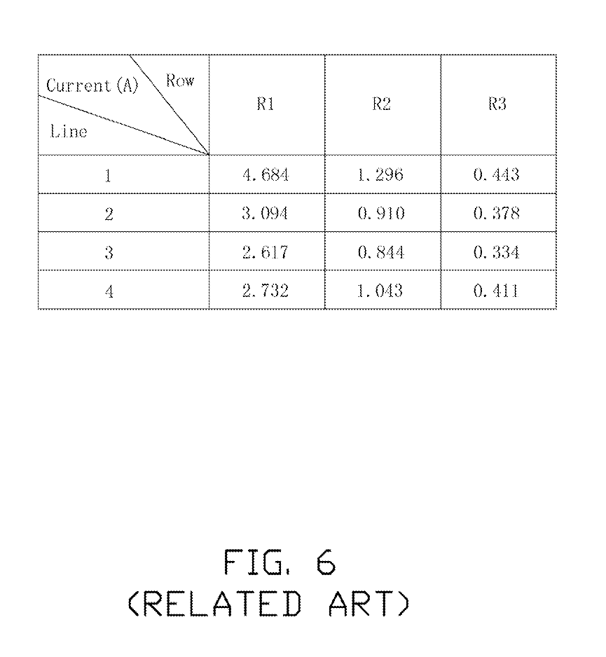

### DETAILED DESCRIPTION

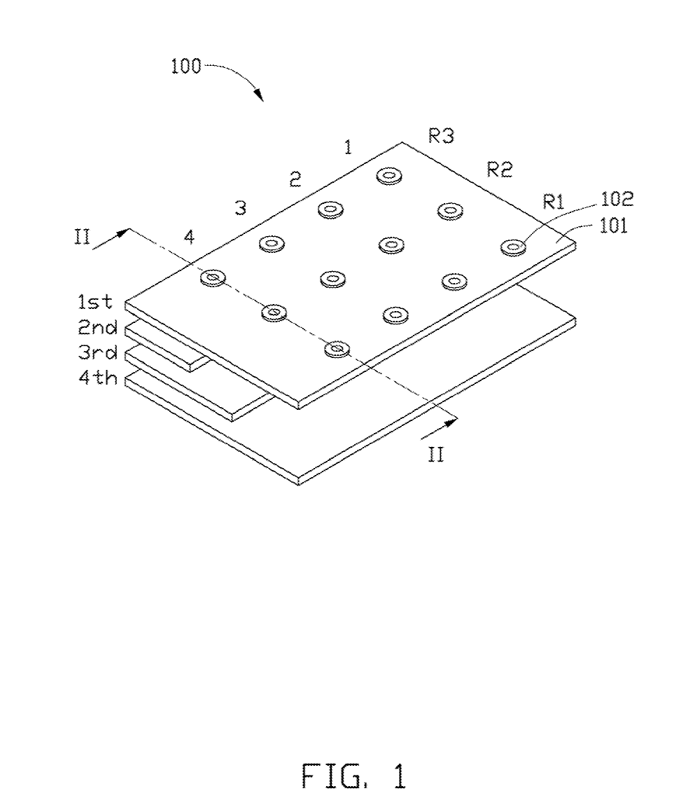

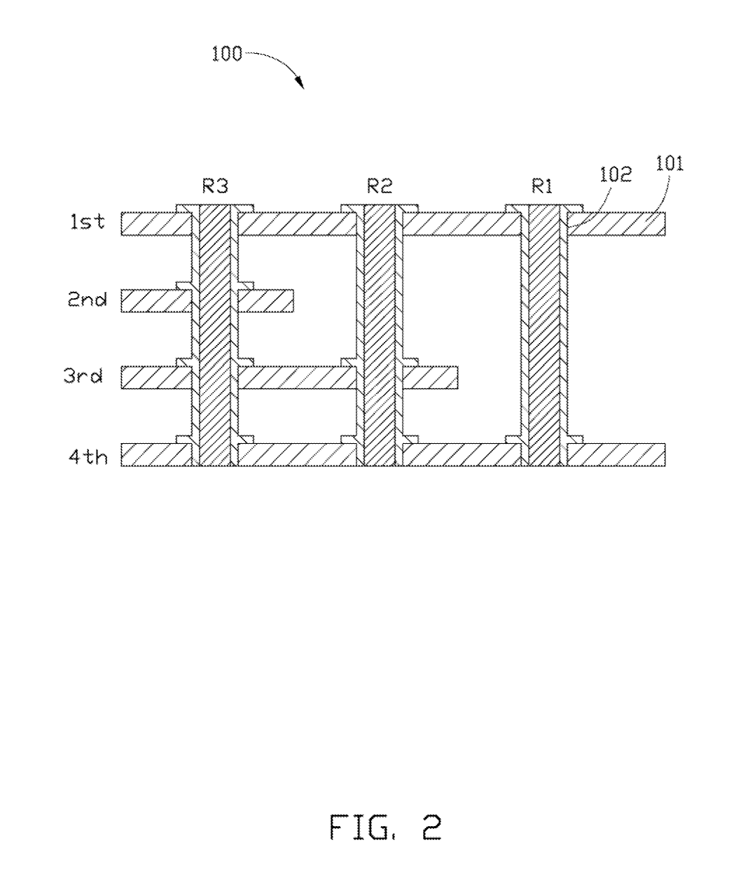

Referring to FIG. 1 and FIG. 2, a printed circuit board 100 includes an N number of power layers 101, where N is a natural number greater than three. A plurality of vias 102 are defined in each power layer 101. The vias 102 defined in the 1st power layer 101 are arranged in (N−1) rows. The vias 102 defined in the 2nd power layer 101 are arranged in one row. Numbers of rows of the vias 102 defined in subsequent power layers 101 are increased one by one until the number of rows of the vias 102 defined in the Nth power layer 101 is (N−1).

Width of the 2nd power layer is wider than that of the 1st power layer. Widths of subsequent power layers 101 are gradually increased until the width of the Nth power layer 101 is substantially equal to that of the 1st power layer 101. Further, the vias 102 arranged in the 1st row of the 1st power layer 101 are adjacent to a power supply (not shown) of the printed circuit board 100. The vias 102 arranged in the (N−1)th row of the 1st power layer 101 are adjacent to loads (not shown) of the printed circuit board 100. The power supply supplies electrical power to the loads through the vias 102 arranged in the 1st row to the (N−1) row.

For the purpose of simplicity and easy of understanding, in this exemplary embodiment, N equals 4. The printed circuit board 100 includes 1st to 4th power layers 101. The vias 102 defined in the 1st power layer 101 are arranged in three rows. The vias 102 defined in the 2nd power layer 101 are arranged in one row. The vias 102 defined in the 3rd power layer 101 are arranged in two rows. The vias 102 defined in the 4th power layer 101 are arranged in three rows (N−1). That is, the number of rows of the vias 102 arranged in of subsequent power layer 101 are increased one by one.

The vias 102 arranged in the 1st row of the 1st power layer 101 are connected to the corresponding vias 102 of the 4th power layer 101. The vias 102 arranged in the 2nd row of the 1st power layer 101 are connected to the corresponding vias 102 of the 3rd and 4th power layers 101. The vias 102 arranged in the 3rd row of the 1st power layer 101 are connected to the corresponding vias 102 of the 2nd, 3rd and 4th power layers 101. That is, the vias 102 arranged in the 3rd row are connected to all the other power layers 101. The vias 102 of the 1st power layer 101 form a step-shaped connection means with other power layers 101

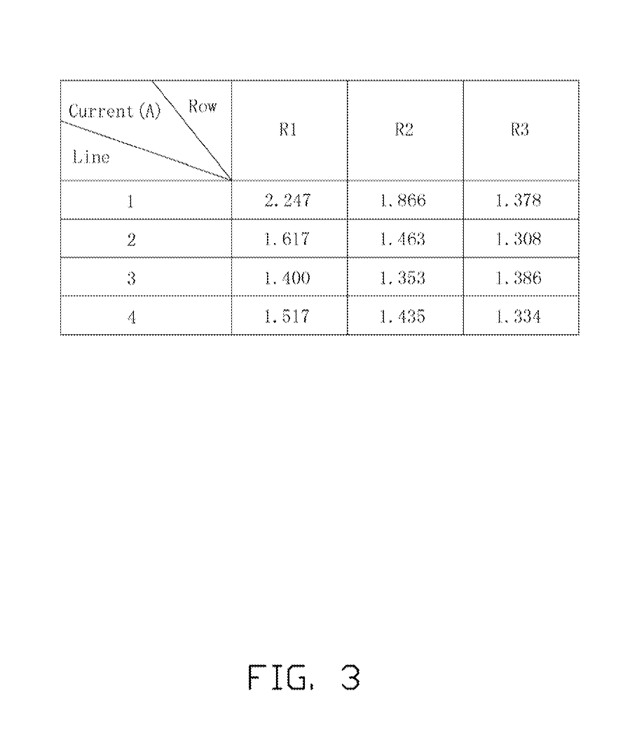

Referring to FIG. 3, current flowing through the vias 102 of the 1st power layer 101 only differ from each other across a relatively small range. Maximum current value of the vias 102 is 2.247 A compared to 4.684 A of a typical printed circuit board, and a minimum current value of the vias 102 is 1.308 A compared to 0.334 A of the the typical printed circuit board. With the current flowing through the vias 102 falling within such a small range, overheating of certain areas of the printed circuit board 100 is effectively avoided.

In other exemplary embodiments, when the vias 102 of the 1st power layer 101 are arranged in (N−1) rows, the vias 102 are connected to the other power layers 101 in the step-shaped connection means. In other words, the vias 102 arranged in the 1st row of the 1st power layer 101 are connected to the corresponding vias 102 of the Nth power layer 101, the vias 102 arranged in the 2nd row of the 1st power layer 101 are connected to the Nth and (N−1)th power layer 101, the vias 102 arranged in the 3rd row of the 1st power layer 101 are connected to the Nth, (N−1)th and (N−2)th power layer 101, and so on until the vias 102 arranged in the (N−1)th row are connected to all the other power layer 101 (i.e. from the 2nd power layer 101 to the (N−1)th power layer).

In addition, when the number of the rows in which the vias 102 of the 1st power layer 101 are arranged is greater than (N−1), the vias 102 can be divided into (N−1) portions. The (N−1) portions of the vias 102 respectively correspond to the (N−1) rows of the vias 102 described above. A portion of the vias 102 adjacent to the power supply corresponds to the vias 102 arranged in the 1st row. A portion of the vias 102 adjacent to the loads corresponds to the vias 102 arranged in the (N−1)th row. The connection means by which the (N−1) portions of the vias 102 are connected is substantially similar to the step-shaped connection means described above. That is, the 1st portion of the vias 102 are connected to the Nth power layer 101, the 2nd portion of the vias 102 are connected the Nth and (N−1)th power layer 101, the 3rd portion of the vias 102 are connected to the Nth, (N−1)th and (N−2)th power layer 101, and so on until the (N−1)th portion of vias 102 are connected to all the other power layers 101(i.e. from the 2nd power layer 101 to the (N−1)th power layer). Moreover, the number of rows of vias 102 of each portion can be adjusted to change actual current flowing through the printed circuit board 100 in any particular application.

When the number of the rows in which the vias 102 of the 1st power layer 101 are arranged is less than (N−1), the vias 102 adjacent to the power supply correspond to the 1st row of vias 102. The vias 102 arranged in the remaining rows of the 1st power layer 101 are connected to other power layers 101 by the step-shaped connection means until a last row of the vias 102, which are connected to other power layers 101.

The vias 102 of the 1st power layer 101 form the step-shaped connection means with others power layers 101, that makes the current flowing through the printed circuit board 100 more even, and can prevent overheating in areas with more current.

It is believed that the exemplary embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A printed circuit board, comprising:
a plurality of power layers, each power layer defining a plurality of vias arranged in a plurality of rows; wherein the number of the power layers is N and N is a natural number greater than three;
when the number of the rows of the 1st power layer is not less than (N−1), the vias of the 1st power layer are divided into (N−1) portions, the 1st portion of the vias of the 1st power layer are connected to the vias of the Nth power layer, the 2nd portion of the vias of the 1st power layer are connected to the vias of the Nth and (N−1)th power layers, the 3rd portion of the vias of the 1st power layer are connected to the Nth, (N−1)th and (N−2)th power layers, and so on until the (N−1)th portion of the vias of the 1st power layer are connected to the vias of all the other power layers; and
when the rows of the 1st power layer is less than (N−1), the vias arranged in the 1st row of the 1st power layer are connected to the vias of the Nth power layer, the vias arranged in the 2nd of the 1st power layer are connected to the vias of the Nth and (N−1)th power layer, and so on until the vias arranged in the last row of the 1st power layer are connected to the vias of the other power layers.

2. The printed circuit board as claimed in claim 1, wherein width of the 2nd power layer is wider than width of the 1st power layer, the widths of subsequent power layers of the 2nd power layer increase one by one until the width of the Nth power layer is equal to width of the 1st power layer.

3. The printed circuit board as claimed in claim 1, wherein when N equals four, the vias defined in the 1st power layer is arranged in three rows, the vias defined in the 2nd power layer is arranged in one row, the vias defined in the 3rd power layer is arranged in two rows, the vias defined in the 4th power layer is arranged in three rows, the vias of the 1st power layer arranged in the 1st row is connected to the 4th power layer, the vias of the 1st power layer arranged in the 2nd row is connected to the 4th and 3rd power layer; the vias of the 3rd power layer arranged in the 1st row is connected to the 4th, 3rd and 2nd power layer.

4. The printed circuit board as claimed in claim 1, wherein the 1st portion of the vias are adjacent to a power supply, the (N−1)th portion of the vias are adjacent to loads.

5. The printed circuit board as claimed in claim 1, wherein numbers of rows of each portion of the vias can be adjusted to change current flowing through the printed circuit board.
